(19) United States
(12) Patent Application Publication
(10) Pub. No.: US 2006/0141769 A1
(43) Pub. Date: Jun. 29, 2006

(54) Method for forming metal line of semiconductor device

(76) Inventor: Jae Suk Lee, Suwon city (KR)

Correspondence Address: MCKENNA LONG & ALDRIDGE LLP;Song K. Jung, 1900 K Street, N.W., Washington, DC, 20006, US

(21) Appl. No.: 11/312,506

(22) Filed: Dec. 21, 2005

(30) Foreign Application Priority Data
Dec. 24, 2004 (KR) 10-2004-0112032

(51) Int. Cl. H01L 21/4763

(52) U.S. Cl. 438/627; 438/687; 438/638; 438/710

(57) ABSTRACT

A method for forming a metal line of a semiconductor device is provided, in which a Cu residue and a mixture of different materials generated after a planarization process are completely removed to improve reliability of the metal line. The method includes removing copper residue on a semiconductor substrate by performing back etching using He plasma in a state where a DC bias is applied to the semiconductor substrate in which the Cu line is formed, and selectively removing the barrier metal film and the dielectric film remaining on the semiconductor substrate by using He plasma in a state where an RF bias is applied to the semiconductor substrate.

### CROSS REFERENCE TO RELATED APPLICATIONS

This application claims the benefit of Korean Patent Application No. 10-2004-0112032, filed on Dec. 24, 2004, which is hereby incorporated by reference as if fully set forth herein.

### BACKGROUND OF THE INVENTION

1. Field of the Invention

The present invention relates to semiconductor devices, and more particularly, to a method for forming a metal line in a semiconductor substrate, in which reliability of the metal line is improved.

2. Discussion of the Related Art

Aluminum and aluminum alloys are the most widely used materials in the manufacture of a semiconductor device because they exhibit good electrical conductivity, have excellent adhesion with an oxide film, and are easy to form. These materials, however, have problems in electrical mobility of material, hillock formation, and spiking. When a current flows in an aluminum metal line, atoms of aluminum are diffused in a high current density region such as a contact region with silicon and a step region. For this reason, a metal line in the high current density region becomes thin and causes shorts. This is called the “electrical mobility” of the material. The electrical mobility of the material is caused after a considerable time as a small amount of atoms is slowly diffused.

An aluminum-copper alloy is used to improve step coverage and the contact region is designed to have a sufficiently wide area.

Spiking is caused by the silicon migrating to an aluminum thin film during annealing. A device is destroyed due to excessive response of a local area. However, this may be solved by using an aluminum-silicon alloy, with the silicon being added at a content greater than solubility. To avoid spiking a thin metal layer, such as to form a diffusion barrier, of for example TiW or PtSi must be inserted between the aluminum and silicon.

Development of a substitute material of the metal line is therefore desired. Examples of the substitute material include Cu, Au, Ag, Co, Cr, and Ni, which are all materials of excellent conductivity. Among these, copper and copper alloys are widely used because these materials exhibit a low specific resistance and excellent reliability in terms of electro migration and stress migration and enable lower production costs. Metal lines of copper and copper alloys are formed by, for example, depositing copper in a via hole (or contact hole) and a trench having a dual damascene structure, to simultaneously form a plug and a metal line, with excess copper being removed from the surface of a wafer by chemical-mechanical polishing. Since copper is easily oxidized and easily dissolved in the slurry used for the chemical-mechanical polishing, however, copper is known as a metal that is difficult to be planarized.

FIGS. 1A-1E illustrate a method for forming a metal line of a semiconductor substrate according to the related art.

As shown in FIG. 1A, a dielectric film 12 is formed on a semiconductor substrate 11 and selectively removed by photolithographic and etching processes to partially expose a surface of the semiconductor substrate 11. Thus, a trench and via hole 13 having a dual damascene structure is formed.

As shown in FIG. 1B, a barrier metal film 14 of a conductive material such as Ti or TiN is formed on an entire surface of the semiconductor substrate 11 including the trench and via hole 13. Subsequently, a Cu thin film 15 is formed on the barrier metal film 14.

As shown in FIG. 1C, a Cu line 16 is formed in the trench and via hole 13 by chemical-mechanical polishing the entire surface of the Cu thin film 15. However, the Cu thin film 15 is easily oxidized by the slurry used for the chemical-mechanical polishing, and therefore, it is difficult to plarnarize.

As shown in FIG. 1C, a copper residue A remains even after completion of the chemical-mechanical polishing. Therefore, after the chemical-mechanical polishing step, a “touch up” process is performed to reduce bridging between metal lines and remove the barrier metal film. For this process, an inorganic chemical such as citric acid is typically used. However, this “touch up” process may ultimately adversely affect reliability of the metal line.

### SUMMARY OF THE INVENTION

Accordingly, the present invention is directed to a method for forming a metal line of a semiconductor device, which substantially obviates one or more problems due to limitations and disadvantages of the related art.

An advantage of the present invention is that it provides a method for forming a metal line of a semiconductor device in which a copper residue and a mixture of different materials generated after a planarization process are completely removed to improve reliability of the metal line.

Additional advantages and features of the invention will be set forth in part in the description which follows and in part will become apparent to those having ordinary skill in the art upon examination of the following or may be learned from practice of the invention.

To achieve these and other advantages in accordance with an embodiment of the present invention, as embodied and broadly described herein, there is provided a method for forming a metal line of a semiconductor device, the method comprising forming a dielectric film on an entire surface of a semiconductor substrate; forming a trench and via hole having a dual damascene structure by selectively removing the dielectric film to partially expose the surface of the semiconductor substrate; forming a barrier metal film on the entire surface of the semiconductor substrate including the trench and via hole; depositing a Cu thin film on the barrier metal film; forming a Cu line in the trench and via hole by performing a planarization process on an entire surface of the Cu thin film; removing a Cu residue on the semiconductor substrate by performing an etch-back process using He plasma with a DC bias applied to the semiconductor substrate in which the Cu line is formed; and selectively removing the barrier metal film and the dielectric film remaining on the semiconductor substrate by using He plasma with an RF bias applied to the semiconductor substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principle of the invention.

In the drawings:

FIGS. 1A-1C are sectional views of a contemporary semiconductor substrate, respectively illustrating process steps in a method for forming a metal line of a semiconductor substrate according to related art; and

FIGS. 2A-2E are sectional views of a semiconductor substrate, respectively illustrating process steps in a method for forming a metal line of a semiconductor substrate according to an embodiment of the present invention.

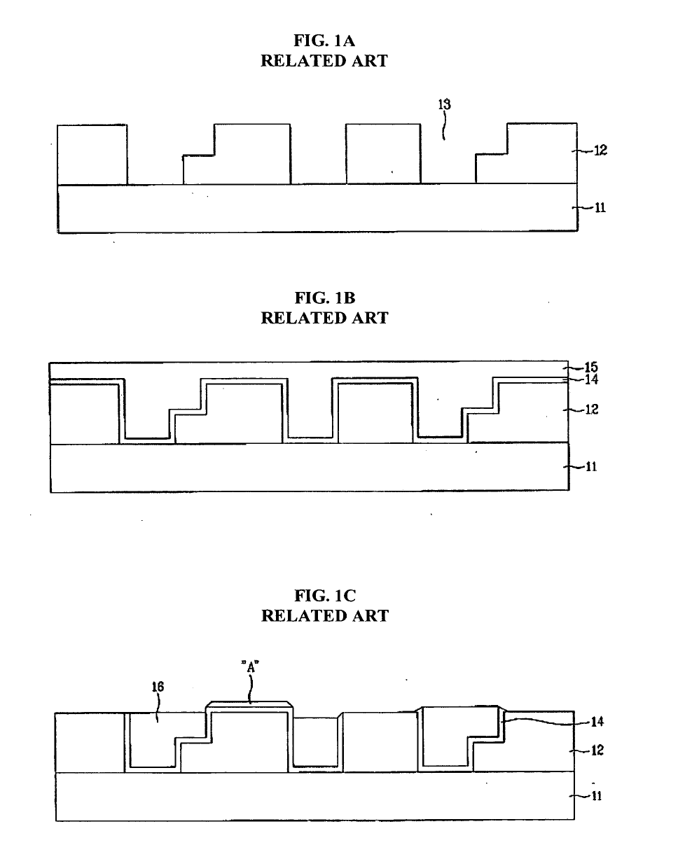

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

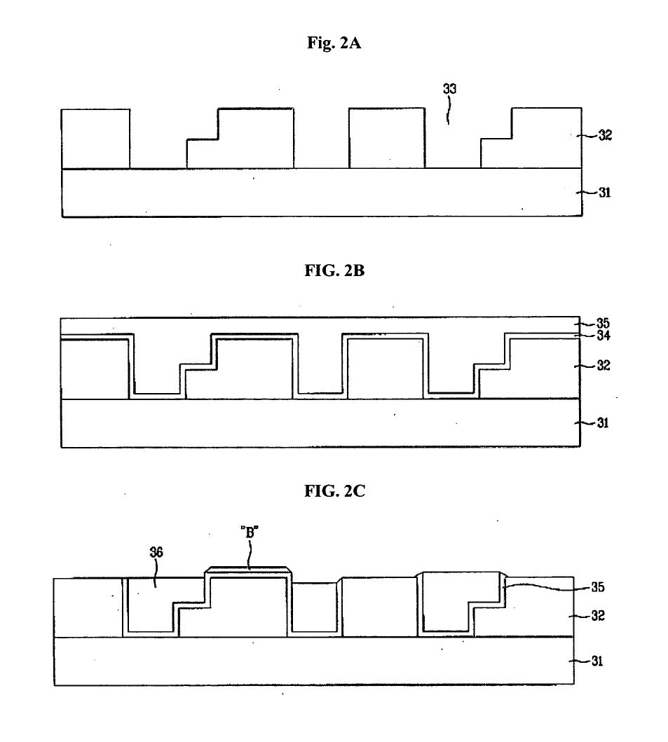

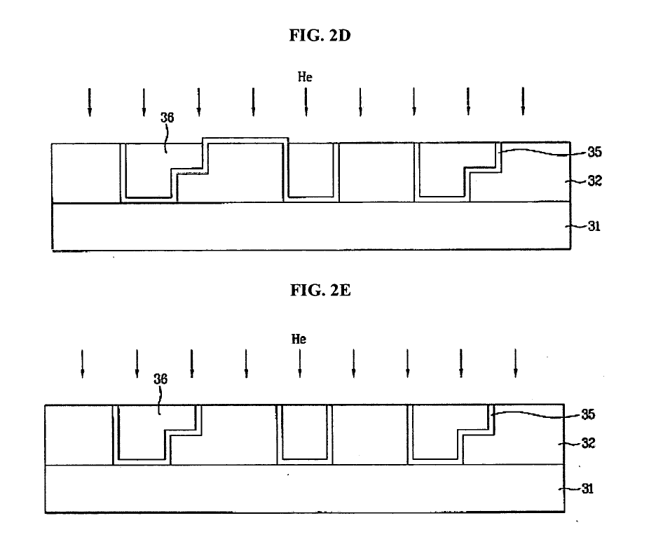

FIGS. 2A-2E illustrate a method for forming a metal line of a semiconductor substrate according to an exemplary embodiment of the present invention.

As shown in FIG. 2A, a dielectric film 32 is formed on a semiconductor substrate 31 and selectively removed by photolithographic and etching processes to partially expose a surface of the semiconductor substrate 31. Thus, trench and via holes having a dual damascene structure may be formed.

As shown in FIG. 2B, a barrier metal film 34 of a conductive material is formed on an entire surface of the semiconductor substrate 31 including the trench and via hole 33. The barrier metal film 34 is formed by depositing TiN, Ta, TaN, WNₓ, or TiAl(N) at a thickness of approximately 10 Å to 1000 Å using a physical vapor deposition or a chemical vapor deposition. The barrier metal film 34 serves to prevent copper (Cu) atoms of a Cu thin film, which will be formed later, from being diffused into the dielectric film 32.

Subsequently, a Cu thin film 35 is formed on the barrier metal film 34 by electroplating. The electroplating essentially requires deposition of a stable and clear Cu seed layer. Alternatively, the electroplating is performed using copper electroplating equipment after an anti-diffusion layer and a Cu seed layer are deposited by a physical vapor deposition or chemical vapor deposition that is carried out in a specific chamber.

The Cu thin film 35 is formed by forming a Cu seed layer and depositing copper on the Cu seed layer using metal-organic chemical vapor deposition or electroplating while under a vacuum i.e., without breaking the vacuum. If the Cu thin film is deposited by metal-organic chemical vapor deposition a deposition temperature is maintained between 50° C. and 300° C. and a precursor of 5 sccm to 100 sccm is used. The precursor may be a mixture of (hfac)Cu(tmvs) and an additive, a mixture of (hfac)Cu(vtmos) and an additive, or a mixture of (hfac)Cu(pentene) and an additive. If the Cu thin film 35 is deposited by electroplating, copper is deposited at a low temperature of −20° C. to 150° C., while under a vacuum, after a Cu seed layer is formed.

As shown in FIG. 2C, a Cu line 36 is formed in the trench and via hole 33 by chemical-mechanical polishing the entire surface of the Cu thin film 35. During the polishing step, the Cu thin film 35 is easily oxidized and dissolved in the slurry used for the chemical-mechanical polishing. Even if a touch up process is performed, an unwanted copper residue B or a mixture of copper and different materials may remain.

As shown in FIG. 2D, a DC bias is applied to the semiconductor substrate 31. In this state, an etch-back process is performed using He plasma, with the applied DC bias by a power source of 1000 kW at 5 Torr or greater in a spacing less than 5 mm. In this manner, copper and the barrier metal are removed by the etch-back process. During this process, the exposed barrier metal film 34 is also partially removed.

As shown in FIG. 2E, an RF bias is applied to the semiconductor substrate 31. In this state, the barrier metal film 34 and the dielectric film 32 are selectively sputtered using He plasma. The residue of the barrier metal film 34 and the dielectric film 32 are removed at a predetermined thickness to impart the touch up effect of the related art. As a result, it is possible to obtain a clear surface in which the copper residue does not occur when the Cu line 36 is formed. The RF bias is applied to the semiconductor substrate 31 under the same condition as that of the DC bias.

By adopting the method for forming a metal line of a semiconductor device according to an embodiment of the present invention, since the copper residue may be completely removed by performing the etch-back process through He plasma with the DC bias and RF bias applied to the substrate after a chemical-mechanical polishing step, bridging between the metal lines can be avoided, thereby improving reliability of the metal line.

It will be apparent to those skilled in the art that various modifications and variations can be made in the present invention without departing from the spirit or scope of the invention. Thus, it is intended that the present invention cover such modifications and variations provided they come within the scope of the appended claims and their equivalents.

What is claimed is:

1. A method for forming a metal line of a semiconductor device, comprising:
forming a dielectric film on an entire surface of a semiconductor substrate;
forming a trench and via hole having a dual damascene structure by selectively removing the dielectric film to partially expose the surface of the semiconductor substrate;
forming a barrier metal film on the entire surface of the semiconductor substrate including the trench and via hole;
depositing a Cu thin film on the barrier metal film;
forming a Cu line in the trench and via hole by performing a planarization process on an entire surface of the Cu thin film;
removing a Cu residue on the semiconductor substrate by performing an etch-back process using He plasma with a DC bias applied to the semiconductor substrate in which the Cu line is formed; and
selectively removing the barrier metal film and the dielectric film remaining on the semiconductor substrate by using He plasma with an RF bias applied to the semiconductor substrate.

2. The method as claimed in claim 1, wherein the DC bias is applied at least 5 Torr.

3. The method as claimed in claim 1, wherein the DC bias has a spacing less than 50 mm.

4. The method as claimed in claim 1, wherein the DC bias is applied by a power source of 1000 kW.

5. The method as claimed in claim 1, wherein the RF bias is applied at least 5 Torr.

6. The method as claimed in claim 1, wherein the RF bias has a spacing less than 50 mm.

7. The method as claimed in claim 1, wherein the RF bias is applied by a power source of 1000 kW.
